(19) United States
(12) Patent Application Publication
(10) Pub. No.: US 2025/0112104 A1
(43) Pub. Date: Apr. 3, 2025

(54) RADIATOR TYPE HEATING ELEMENT FOR INTEGRATED CIRCUITS

(71) Applicant: OpenLight Photonics, Inc., Goleta, CA (US)

(72) Inventor: John Sonkoly, Laguna Niguel, CA (US)

(21) Appl. No.: 18/375,772

(22) Filed: Oct. 2, 2023

(51) Int. Cl. H01L 23/34

(52) U.S. Cl. CPC H01L 23/345

(57) ABSTRACT

A device includes a heating element occupying at least a portion of a layer of an integrated circuit (IC). The IC includes a plurality of layers stacked in a lamination direction and a target component. A plurality of thermally conductive structures extends from the heating element through one or more layers of the plurality of layers of the IC. The plurality of thermally conductive structures overlaps at least a portion of the target component in a lateral direction perpendicular to the lamination direction.

### TECHNICAL FIELD

The present disclosure generally relates to integrated circuits and more particularly to heating elements of integrated circuits.

### BACKGROUND

Temperature sensitive components in integrated circuits (ICs) are often heated in order to adjust their parameters. Heating elements, also called heaters, may be used in an IC to heat these temperature sensitive components.

### BRIEF DESCRIPTION OF THE SEVERAL VIEWS OF THE DRAWINGS

The following description includes discussion of figures having illustrations given by way of example of implementations of embodiments of the disclosure. The drawings should be understood by way of example, and not by way of limitation. As used herein, references to one or more “examples” or “embodiments” are to be understood as describing a particular feature, structure, or characteristic included in at least one implementation of the inventive subject matter, in at least some circumstances. Thus, phrases such as “in one example”, “in some examples”, “in some embodiments”, “in one embodiment” or “in an alternate embodiment” appearing herein describe various embodiments and implementations of the inventive subject matter, and do not necessarily all refer to the same embodiment. However, they are also not necessarily mutually exclusive. To easily identify the discussion of any particular element or act, the most significant digit or digits in a reference number may refer to the figure (“FIG.”) number in which that element or act is first introduced.

FIG. 1 illustrates a perspective view of a conventional IC heater device having a thin, wide heating element positioned within a single layer of an IC, providing context for discussion of examples described herein.

FIG. 2 illustrates a perspective view of a first example IC heater device having fins extending upward from a heating element to heat an IC component, in accordance with at least one example.

FIG. 3 illustrates a plan view of the first example IC heater device, in accordance with at least one example.

FIG. 4 illustrates a cross-sectional side view of a thermally conductive structure and the heating element of the first example IC heater device through line A-A in FIG. 3, in accordance with at least one example.

FIG. 5 illustrates a perspective view of a second example IC heater device having fins extending upward along only a portion of a length of a heating element to non-uniformly heat an IC component, in accordance with at least one example.

FIG. 6 illustrates a perspective view of a third example IC heater device having fins electrically connecting multiple segments of a heating element, in accordance with at least one example.

FIG. 7 illustrates a perspective view of a fourth example IC heater device having fins extending downward from a heating element on two opposing sides of an IC component to be heated, in accordance with at least one example.

FIG. 8 illustrates a method for manufacturing an integrated circuit, in accordance with at least one example.

Descriptions of certain details and implementations follow, including a description of the figures, which may depict some or all of the embodiments described below, as well as discussing other potential embodiments or implementations of the inventive concepts presented herein. An overview of embodiments of the disclosure is provided below, followed by a more detailed description with reference to the drawings.

### DETAILED DESCRIPTION

In the following description, for the purposes of explanation, numerous specific details are set forth in order to provide an understanding of various embodiments of the inventive subject matter. It will be evident, however, to those skilled in the art, that embodiments of the inventive subject matter may be practiced without these specific details. In general, well-known instruction instances, structures, and techniques are not necessarily shown in detail.

An IC is typically manufactured by forming a stack of layers. Conventional resistive heaters in ICs are typically confined to one thin layer within the stack of layers of the IC. The heat diffusion distribution from such a thin, wide heater is typically concentrated in the direction perpendicular to the layer, also referred to as the lamination direction of the layers of the IC; the lamination direction may be referred to herein as a vertical direction (e.g., “up” or “down”) regardless of the orientation of the IC in relation to gravity when the IC is in use. A relatively small portion of this heat is diffused laterally (i.e., sideways, perpendicularly to the lamination direction). However, the component that is to be heated often is located to the side of the heater. Therefore, it may be beneficial in some cases to provide a heater for IC components that can transfer heat to the side more efficiently than existing approaches to heating IC components.

Prior approaches to heating IC components located to the side of the heater have involved either locating the heater very close to the IC component to be heated (also called the heater target, target component, target IC component, target device, or simply target), and/or thermally isolating the heater to channel its heat toward the IC component to be heated. However, there are physical constraints on how close the heater can be to the target IC component. Furthermore, thermal isolation of the heater may give rise to reliability issues and may result in thermal isolation of the target IC component as well, making the target IC component more susceptible to self-heating.

Accordingly, examples described herein may attempt to address one or more technical problems related to the lateral heating of IC components.

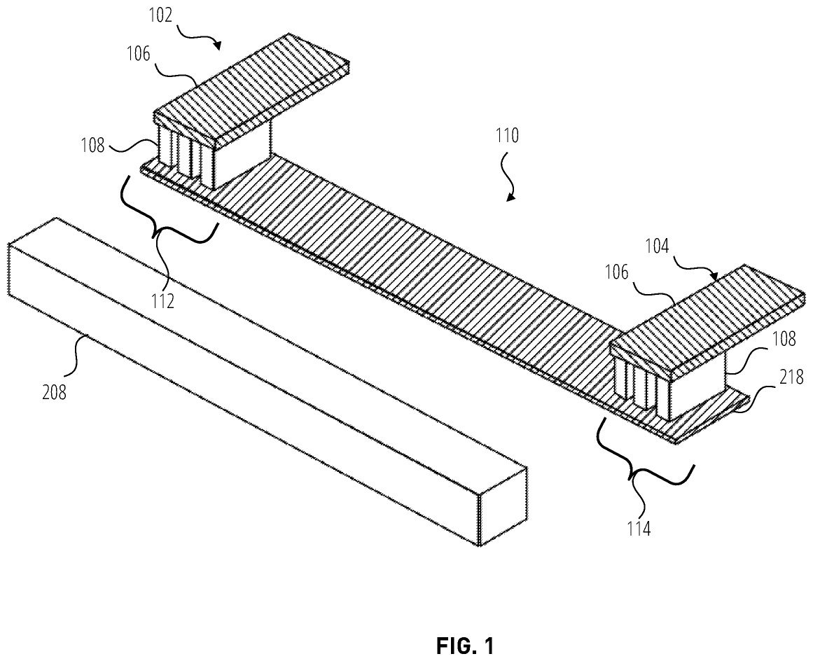

FIG. 1 shows an IC heater device, shown as heater 110, in accordance with existing approaches to IC heater design. The heater 110 has a thin, wide heating element 218 positioned within a single layer of an IC. The heater 110 is shown in isolation, but would typically be embedded within layers of the IC. In some cases, the heater 110 is electrically isolated from other components of the IC by insulating material such as a dielectric material of the various IC layers.

A first end electrical connection 102 and a second end electrical connection 104 are connected to the heating element 218 to pass a current through the heating element 218. Each of the electrical connections 102, 104 includes a trace 106 situated within a different layer of the IC from the IC layer occupied by the heating element 218, and one or more electrical connection vias 108 electrically connecting the trace 106 to the heating element 218 by passing through any intervening layers of the IC. The first end electrical connection 102 is in electrical communication with a first region 112 of the heating element 218, and the second end electrical connection 104 is in electrical communication with a second region 114 of the heating element 218, such that the first end electrical connection 102 and second end electrical connection 104 are configured to pass the electrical current between the first region 112 and second region 114 through the heating element 218.

In some examples, the heating element 218 is substantially composed of a highly resistive material such that, in response to the current passing through the heating element 218, heat is generated by the heating element 218 and radiated outward toward other components of the IC in which the heater 110 is embedded.

The heater 110 is intended to heat a target component 208 located laterally to the heater 110. As described above, the ability of the conventional heater 110 to radiate heat toward the target component 208 is limited by various constraints. Instead, the heater 110 will tend to radiate most of its heat upward and downward from the wide, flat planar surfaces of the heating element 218, instead of laterally toward the target component 208.

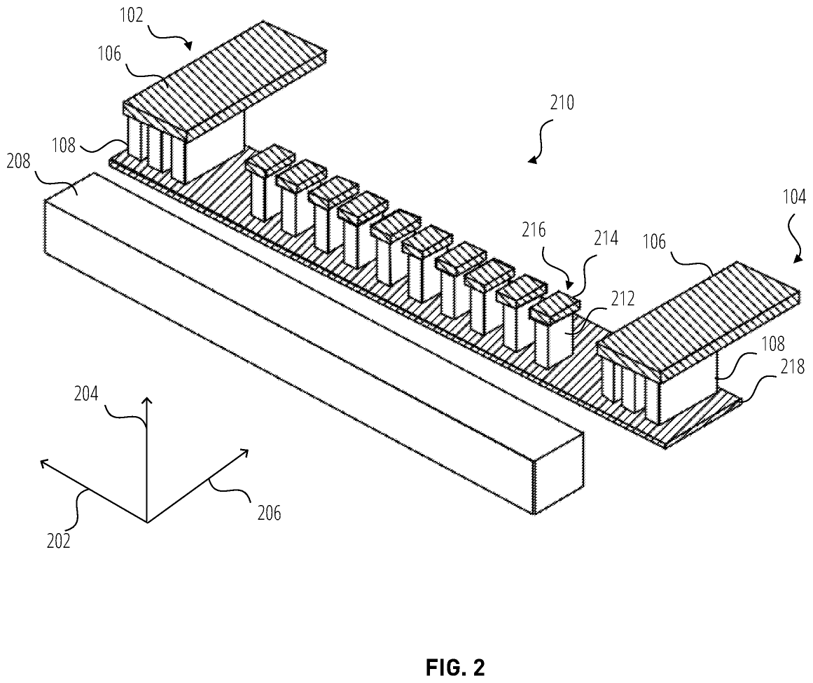

FIG. 2 shows a first example IC heater device 210 having a set of thermally conductive structures 216 extending upward from a heating element 218 to improve lateral radiation of heat toward the target component 208. As in the conventional heater 110 of FIG. 1, the device 210 is in a lateral direction 206 from the target component 208. The lateral direction 206 is perpendicular to the lamination direction 204. A longitudinal direction 202 is also shown, perpendicular to both the lamination direction 204 and the lateral direction 206.

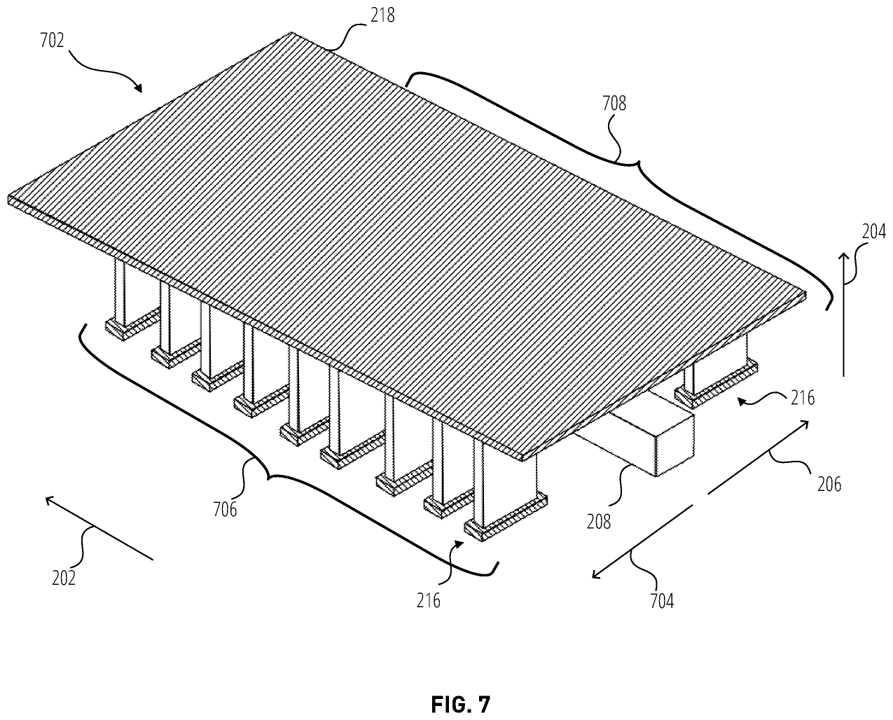

As used herein, “lateral” or “laterally” may refer to either the lateral direction 206 or a direction opposite the lateral direction 206, such as opposite lateral direction 704 shown in FIG. 7.

The IC in which the device 210 is embedded includes a stack of layers stacked in the lamination direction. The target component 208 is laterally spaced apart from the device 210.

In FIG. 2, the thermally conductive structures 216 are shown as fins, each having a thermally conductive plate 214 and a thermally conductive via 212 extending between the heating element 218 and the plate 214. In some examples, the plate 214 and/or the via 212 of the thermally conductive structures 216 are composed substantially of a thermally conductive material in order to conduct heat from the heating element 218, into a first end of the via 212 (e.g., a bottom end of the via 212) in contact with the heating element 218, to a second end of the via 212 (e.g., a top end of the via 212), and into the plate 214 in contact with the second end of the via 212. The heat radiates outward from each via 212 and/or the plate 214; in some examples, a significant portion of this radiation of heat is directly against lateral direction 206, perpendicular to the lamination direction 204, and therefore toward the target component 208.

In some examples, such as the first example device 210 shown in FIG. 2, the thermally conductive structures 216 are arranged along the longitudinal direction 202. The heating element 218 occupies at least a portion of a layer of the IC. The via 212 of each thermally conductive structure 216 extends away (e.g., upward) from the heating element 218 through one or more layers of the IC, and the plate 214 of each thermally conductive structure 216 is located within a different (e.g., a higher) layer of the IC from the layer occupied by the heating element 218.

In some examples, the plate 214 is longer than the via 212 in the longitudinal direction 202. This increases the lateral area of the plate 214, potentially increasing the amount of heat radiated laterally toward the target component 208.

In some examples, the thermally conductive structures 216 are located between the first region 112 and the second region 114 (shown in FIG. 1) along the longitudinal direction 202. The first end electrical connection 102 and second end electrical connection 104 are configured to pass the electrical current between the first region 112 and the second region 114 through the heating element 218, thereby creating resistive heating in the length of the heating element 218 between the first end electrical connection 102 and second end electrical connection 104 and therefore causing conduction of heat into the thermally conductive structures 216.

The spaces in between the thermally conductive structures 216 may be filled with an electrically insulating material, such as a dielectric material. The spacing apart of the thermally conductive structures 216 may permit heat to efficiently radiate laterally outward.

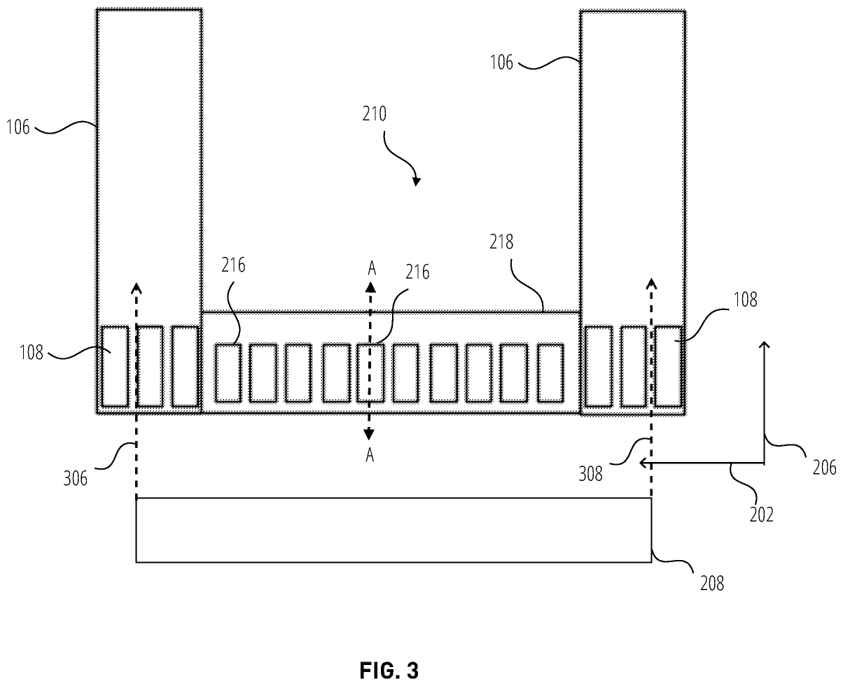

FIG. 3 shows an overhead plan view of the first example IC heater device 210 and target component 208 of FIG. 2. It can be seen in FIG. 3 that the target component 208 may span a distance along the longitudinal direction 202 between a first end of overlap 306 and a second end of overlap 308, defining between the first end of overlap 306 and second end of overlap 308 a horizontal overlap of the target component 208 with the device 210. In some examples, at least one of the thermally conductive structures 216 is located along the longitudinal direction 202 to fall within this region of horizontal overlap, between the first end of overlap 306 and second end of overlap 308.

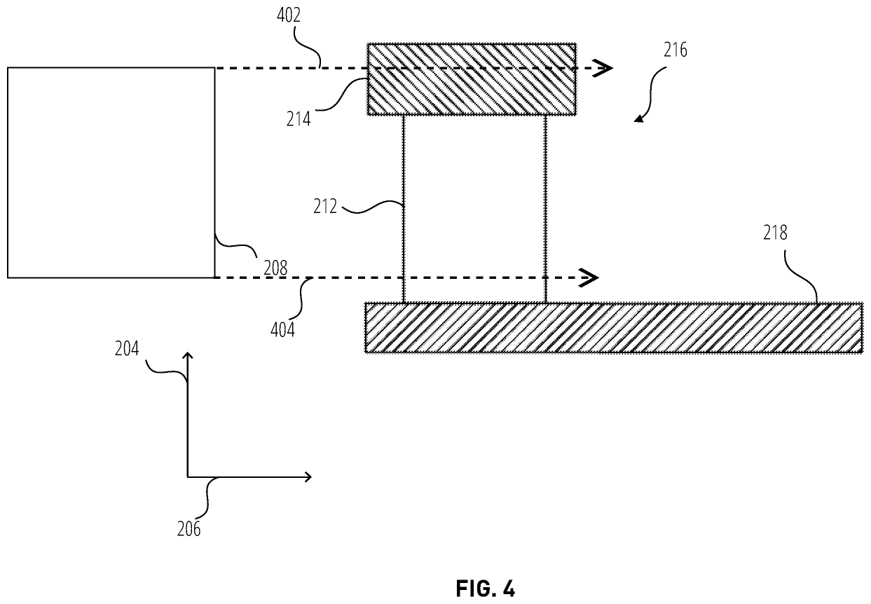

FIG. 4 shows a cross-sectional side view of one of the thermally conductive structures 216 and the heating element 218 of the first example IC heater device 210 through line A-A in FIG. 3.

In some examples, the plate 214 extends toward the target component 208 from the second end (in this example, the top end) of the via 212, in a direction opposite the lateral direction 206. By placing the lateral face of the plate 214 closer to the target component 208, the distance between the plate 214 and the target component 208 is reduced, thereby potentially increasing the amount of heat radiated from the plate 214 to the target component 208.

A vertical overlap of the target component 208 with the device 210 in the lateral direction 206 is defined by a vertical profile of the target component 208 spanning between a top end of overlap 402 and a bottom end of overlap 404. One or more of the thermally conductive structures 216 may be located at least partially within this vertical overlap region, in addition to being located at least partially within the region of horizontal overlap shown in FIG. 3 and defined between the first end of overlap 306 and second end of overlap 308.

Thus, in some examples, the set of thermally conductive structures 216 jointly overlap at least a portion of the target component 208 in the lateral direction 206, by falling at least partially within both the horizontal region of overlap and the vertical region of overlap.

It will be appreciated that, in some cases, the thermally conductive structures 216 may fall entirely outside of the horizontal region of overlap, or outside of the vertical region of overlap. However, the efficiency of lateral heating may be improved in examples having a greater degree of both horizontal and vertical overlap of the thermally conductive structures 216 with the target component 208.

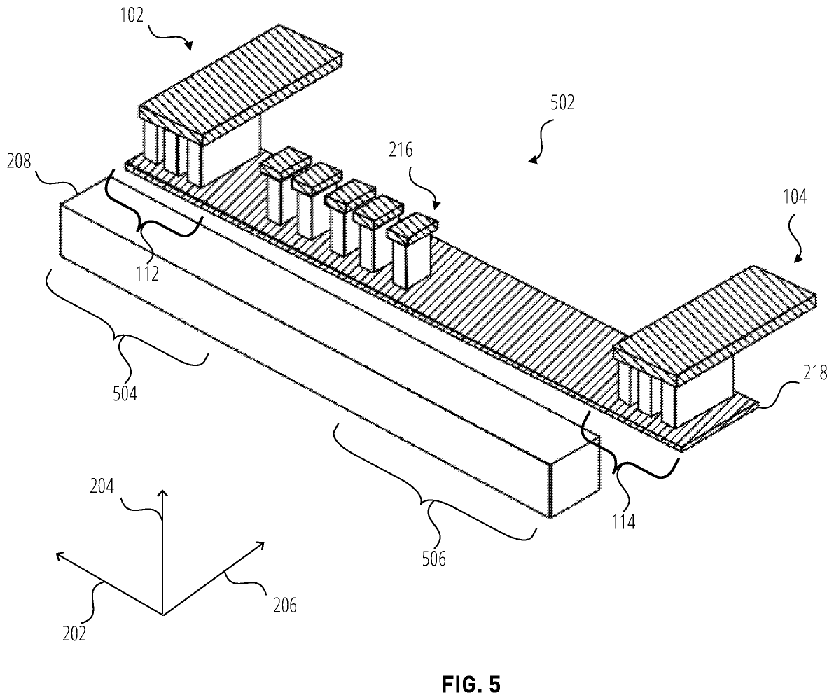

FIG. 5 shows a second example IC heater device 502 having thermally conductive structures 216 arranged along only a portion of a length of the heating element 218.

In some examples, it may be desirable to non-uniformly heat the target component 208 using the device 502. For example, the target component 208 may have a first portion 504 and a second portion 506 at different locations along the longitudinal direction 202, and the second portion 506 may have less need for heating than the first portion 504. In some examples, the second portion 506 may self-heat to a greater degree than the first portion 504 during operation; for example, the second portion 506 may be an input end where the target component 208 receives power or another electrical or optical signal that causes self-heating in the second portion 506 to a greater degree than in the first portion 504. In such cases, it may be desirable to configure the thermally conductive structures 216 of the device 502 such that they radiate a greater amount of heat to the first portion 504 than to the second portion 506.

The configuration shown in FIG. 5 is only one example of how the heat-radiation capabilities of the device 502 may be modulated along the longitudinal direction 202. In some examples, the thermally conductive structures 216 are arranged non-uniformly along the longitudinal direction 202 such that, when the current is passed through the heating element 218, the thermally conductive structures 216 radiate a greater amount of heat toward the first portion 504 of the target component 208 than toward the second portion of the target component 208. In some examples, the thermally conductive structures 216 may be spaced non-uniformly along the longitudinal direction: e.g., the spacing of the thermally conductive structures 216 may be less dense at a region of the heating element 218 lateral from the second portion 506 than at a region of the heating element 218 lateral from the first portion 504. In some examples, the thermally conductive structures 216 may have a respective plurality of sizes that vary along the longitudinal direction 202: e.g., the thermally conductive structures 216 may be smaller, or with smaller plates 214, at a region of the heating element 218 lateral from the second portion 506 than at a region of the heating element 218 lateral from the first portion 504. In some examples, such as in the illustrated device 502, the thermally conductive structures 216 are closer to the first region 112 than the second region 114 of the heating element 218.

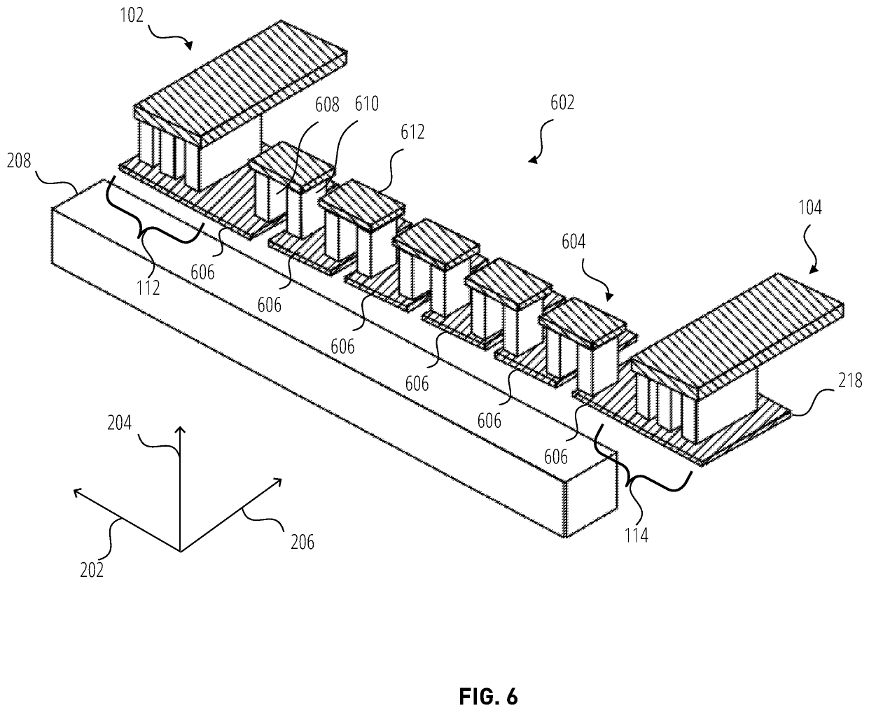

FIG. 6 shows a third example IC heater device 602 having thermally conductive structures 604 electrically connecting multiple heating element segments 606 of the heating element 218. In the illustrated example, the thermally conductive structures 604 conduct both electric current and heat, and may thereby act to generate heat as well as conducting and radiating it. The heating element 218 includes multiple heating element segments 606, each heating element segment 606 being spaced apart from the other heating element segments 606 along the longitudinal direction 202. Each thermally conductive structure 216 includes two electrically conductive vias, first via 608 and second via 610. Each electrically conductive via 608 and 610 has a first end in contact with a respective one of the heating element segments 606, and a second end in contact with an electrically conductive plate 612 shared by both electrically conductive vias 608 and 610, joining the second end of the first via 608 to the second end of the second via 610, such that the current passes between the first region 112 and the second region 114 through each heating element segment 606 and each thermally conductive structure 604. As the current passes through the heating element segments 606, they heat up through resistive heating, and this heat is conducted into the vias 608 and 610 and plate 612 of each thermally conductive structure 604. In some examples, the plates 612 are substantially composed of a material that has a higher resistivity than the first via 608 and the second via 610, such that the plates 612 generate heat when the current passes through them. This heat radiates outward, including laterally toward the target component 208; some of the heat may also conduct into the first via 608 and second via 610, and radiate out in turn toward the target component 208 from the vias 608 and 610.

FIG. 7 shows a fourth example IC heater device 702 having thermally conductive structures 216 extending downward from a heating element 218 on two opposing sides of the target component 208. In this example, the heating element 218 is spaced apart from, and at least partially overlapping, the target component 208 in the lamination direction 204. For example, the heating element 218 may be positioned in a layer above the target component 208, as shown in the example device 702 of FIG. 7. In other examples, the heating element 218 may be in a layer below the target component 208, and/or the heating element 218 may only partially overlap the target component 208.

The thermally conductive structures 216 extend downward from the heating element 218 to form two rows of thermally conductive structures 216: first row 708, arranged along the longitudinal direction 202 in the lateral direction 206 from the target component 208, and second row 706, arranged along the longitudinal direction 202 in an opposite lateral direction 704 (opposite to the lateral direction 206) from the target component 208. Thus, whereas the first row 708 at last partially overlaps the target component 208 in the lateral direction 206, the second row 706 at last partially overlaps the target component 208 in the opposite lateral direction 704.

The device 702 shown in FIG. 7 may radiate heat very efficiently toward the target component 208 due to radiation not only laterally from the first row 708, but also laterally from the second row 706 and downward (against the lamination direction 204) from the bottom planar surface of the heating element 218.

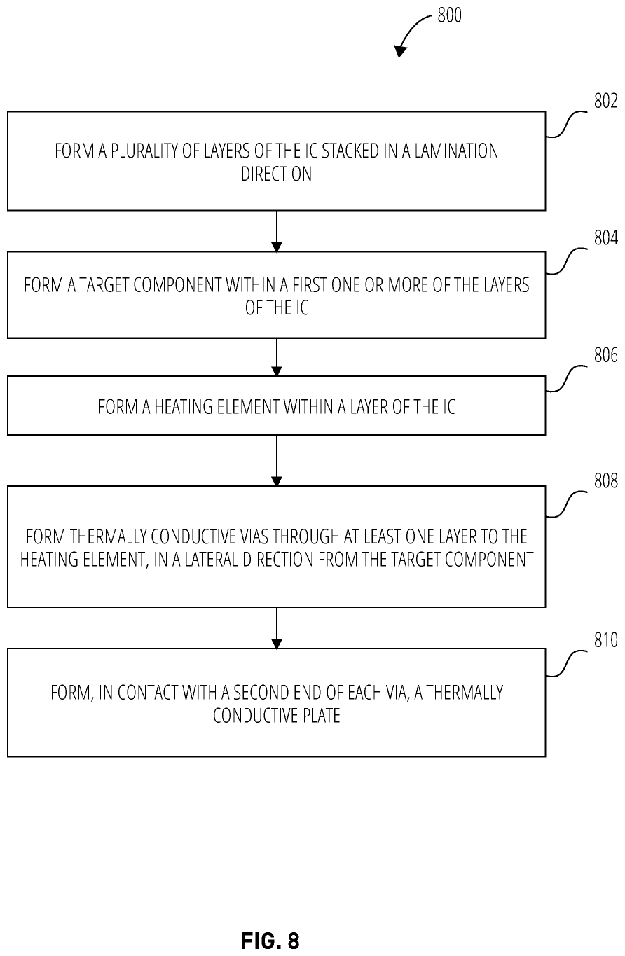

FIG. 8 illustrates an example method 800 for manufacturing an integrated circuit. Although the example method 800 depicts a particular sequence of operations, the sequence may be altered without departing from the scope of the present disclosure. For example, some of the operations depicted may be performed in parallel or in a different sequence that does not materially affect the function of the method 800. In other examples, different components of an example device or system that implements the method 800 may perform functions at substantially the same time or in a specific sequence.

According to some examples, the method 800 includes forming a plurality of layers of the IC stacked in the lamination direction 204 at operation 802.

According to some examples, the method 800 includes forming the target component 208 within a first one or more of the layers of the IC at operation 804.

According to some examples, the method 800 includes forming the heating element 218 within a layer of the IC at operation 806.

According to some examples, the method 800 includes forming the thermally conductive vias (e.g., vias 212) through at least one of the plurality of IC layers to the heating element 218, in the lateral direction 206 from the target component 208, at operation 808.

According to some examples, the method 800 includes forming, in contact with a second end of each via 212, a thermally conductive plate 214 at operation 810.

Examples described herein may thereby provide various techniques for replacing a conventional integrated resistive heater having an essentially two-dimensional planar structure with a three-dimensional structure by adding radiator type fins made of vias passing through layers and plates located in another layer. The various three-dimensional radiator heater devices described herein may provide more effective and/or efficient lateral heating of target components in an IC.

In view of the disclosure above, various examples are set forth below. It should be noted that one or more features of an example, taken in isolation or combination, should be considered within the disclosure of this application.

The following are example embodiments:

Example 1 is a device comprising: a heating element occupying at least a portion of a layer of an integrated circuit (IC), the IC comprising a plurality of layers stacked in a lamination direction, the IC including a target component; and a plurality of thermally conductive structures extending from the heating element through one or more layers of the plurality of layers of the IC, the plurality of thermally conductive structures overlapping at least a portion of the target component in a lateral direction perpendicular to the lamination direction.

In Example 2, the subject matter of Example 1 includes, wherein each thermally conductive structure comprises: a via having a first end in contact with the heating element and a second end; and a plate in contact with the second end of the via, the plate extending toward the target component from the second end of the via.

In Example 3, the subject matter of Example 2 includes, wherein: the plate is longer than the via in a longitudinal direction perpendicular to the lamination direction and the lateral direction.

In Example 4, the subject matter of Examples 1-3 includes, wherein the plurality of thermally conductive structures is arranged along a longitudinal direction perpendicular to the lamination direction and the lateral direction.

In Example 5, the subject matter of Example 4 includes, wherein the plurality of thermally conductive structures is spaced non-uniformly along the longitudinal direction.

In Example 6, the subject matter of Examples 4-5 includes, wherein the plurality of thermally conductive structures has a respective plurality of sizes that vary along the longitudinal direction.

In Example 7, the subject matter of Examples 4-6 includes, a first end electrical connection in contact with a first region of the heating element; and a second end electrical connection in contact with a second region of the heating element, wherein: the plurality of thermally conductive structures is located between the first region and the second region along the longitudinal direction; and the first end electrical connection and second end electrical connection are configured to pass an electrical current between the first region and the second region through the heating element.

In Example 8, the subject matter of Example 7 includes, wherein: the heating element comprises a plurality of heating element segments spaced apart from each other along the longitudinal direction; and each thermally conductive structure comprises: an electrically conductive first via having: a first end in contact with a respective first one of the plurality of heating element segments; and a second end; an electrically conductive second via having: a first end in contact with a respective second one of the plurality of heating element segments; and a second end; and an electrically conductive plate joining the second end of the first via to the second end of the second via, such that the electrical current passes between the first region and the second region through each heating element segment and each thermally conductive structure.

In Example 9, the subject matter of Example 8 includes, wherein: the electrically conductive plate has a higher resistivity than the first via and the second via.

In Example 10, the subject matter of Examples 7-9 includes, wherein: the plurality of thermally conductive structures is closer to the first region than the second region.

In Example 11, the subject matter of Examples 1-10 includes, wherein: the heating element is spaced apart from, and at least partially overlapping, the target component in the lamination direction; and the device further comprises: a further plurality of thermally conductive structures extending from the heating element through one or more of the plurality of layers of the IC, the further plurality of thermally conductive structures overlapping at least a portion of the target component in a direction opposite the lateral direction.

Example 12 is an integrated circuit (IC) comprising: a plurality of layers stacked in a lamination direction; a target component; a heating element occupying at least a portion of a layer of the plurality of layers; and a plurality of thermally conductive structures extending from the heating element through one or more layers of the plurality of layers, the plurality of thermally conductive structures overlapping at least a portion of the target component in a lateral direction perpendicular to the lamination direction.

In Example 13, the subject matter of Example 12 includes, wherein each thermally conductive structure comprises: a via having a first end in contact with the heating element and a second end; and a plate in contact with the second end of the via, the plate extending toward the target component from the second end of the via.

In Example 14, the subject matter of Example 13 includes, wherein: the plate is longer than the via in a longitudinal direction perpendicular to the lamination direction and the lateral direction.

In Example 15, the subject matter of Examples 12-14 includes, wherein the plurality of thermally conductive structures is arranged along a longitudinal direction perpendicular to the lamination direction and the lateral direction.

In Example 16, the subject matter of Example 15 includes, a first end electrical connection in contact with a first region of the heating element; and a second end electrical connection in contact with a second region of the heating element, wherein: the plurality of thermally conductive structures is located between the first region and the second region along the longitudinal direction; and the first end electrical connection and second end electrical connection are configured to pass an electrical current between the first region and the second region through the heating element.

In Example 17, the subject matter of Example 16 includes, wherein: the target component has a first portion and a second portion; the first portion is in the longitudinal direction from the second portion; in operation, the second portion self-heats to a greater degree than the first portion; and the plurality of thermally conductive structures is arranged non-uniformly along the longitudinal direction such that, when the electrical current is passed through the heating element, the plurality of thermally conductive structures radiates a greater amount of heat toward the first portion of the target component than toward the second portion of the target component.

In Example 18, the subject matter of Examples 16-17 includes, wherein: the heating element comprises a plurality of heating element segments spaced apart from each other along the longitudinal direction; and each thermally conductive structure comprises: a first electrically conductive via having: a first end in contact with a respective first one of the plurality of heating element segments; and a second end; a second electrically conductive via having: a first end in contact with a respective second one of the plurality of heating element segments; and a second end; and an electrically conductive plate joining the second end of the first via to the second end of the second via, such that the current passes between the first region and the second region through each heating element segment and each thermally conductive structure.

In Example 19, the subject matter of Examples 12-18 includes, wherein: the heating element is spaced apart from, and at least partially overlapping, the target component in the lamination direction; and the IC further comprises: a further plurality of thermally conductive structures extending from the heating element through one or more of the plurality of layers of the IC, the further plurality of thermally conductive structures overlapping at least a portion of the target component in a direction opposite the lateral direction.

Example 20 is a method of manufacturing an integrated circuit (IC), comprising: forming a plurality of layers of the IC stacked in a lamination direction; forming a target component within a first one or more of the layers of the IC; forming a heating element within a layer of the IC; forming a plurality of thermally conductive vias through at least one of the first one or more layers, such that a first end of each via contacts the heating element, and such that at least one of the thermally conductive vias is in a lateral direction, perpendicular to the lamination direction, from the target component; and forming, in contact with a second end of each via, a thermally conductive plate.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

What is claimed is:

1. A device comprising:
a heating element occupying at least a portion of a layer of an integrated circuit (IC), the IC comprising a plurality of layers stacked in a lamination direction, the IC including a target component; and
a plurality of thermally conductive structures extending from the heating element through one or more layers of the plurality of layers of the IC, the plurality of thermally conductive structures overlapping at least a portion of the target component in a lateral direction perpendicular to the lamination direction.

2. The device of claim 1, wherein each thermally conductive structure comprises:
a via having a first end in contact with the heating element and a second end; and
a plate in contact with the second end of the via, the plate extending toward the target component from the second end of the via.

3. The device of claim 2, wherein:
the plate is longer than the via in a longitudinal direction perpendicular to the lamination direction and the lateral direction.

4. The device of claim 1, wherein the plurality of thermally conductive structures is arranged along a longitudinal direction perpendicular to the lamination direction and the lateral direction.

5. The device of claim 4, wherein the plurality of thermally conductive structures is spaced non-uniformly along the longitudinal direction.

6. The device of claim 4, wherein the plurality of thermally conductive structures has a respective plurality of sizes that vary along the longitudinal direction.

7. The device of claim 4, further comprising:
a first end electrical connection in contact with a first region of the heating element; and
a second end electrical connection in contact with a second region of the heating element,
wherein:
the plurality of thermally conductive structures is located between the first region and the second region along the longitudinal direction; and
the first end electrical connection and second end electrical connection are configured to pass an electrical current between the first region and the second region through the heating element.

8. The device of claim 7, wherein:
the heating element comprises a plurality of heating element segments spaced apart from each other along the longitudinal direction; and
each thermally conductive structure comprises:
an electrically conductive first via having:
a first end in contact with a respective first one of the plurality of heating element segments; and
a second end;
an electrically conductive second via having:
a first end in contact with a respective second one of the plurality of heating element segments; and
a second end; and
an electrically conductive plate joining the second end of the first via to the second end of the second via,
such that the electrical current passes between the first region and the second region through each heating element segment and each thermally conductive structure.

9. The device of claim 8, wherein:
the electrically conductive plate has a higher resistivity than the first via and the second via.

10. The device of claim 7, wherein:
the plurality of thermally conductive structures is closer to the first region than the second region.

11. The device of claim 1, wherein:
the heating element is spaced apart from, and at least partially overlapping, the target component in the lamination direction; and
the device further comprises:
a further plurality of thermally conductive structures extending from the heating element through one or more of the plurality of layers of the IC, the further plurality of thermally conductive structures overlapping at least a portion of the target component in a direction opposite the lateral direction.

12. An integrated circuit (IC) comprising:
a plurality of layers stacked in a lamination direction;
a target component;
a heating element occupying at least a portion of a layer of the plurality of layers; and
a plurality of thermally conductive structures extending from the heating element through one or more layers of the plurality of layers, the plurality of thermally conductive structures overlapping at least a portion of the target component in a lateral direction perpendicular to the lamination direction.

13. The IC of claim 12, wherein each thermally conductive structure comprises:
a via having a first end in contact with the heating element and a second end; and
a plate in contact with the second end of the via, the plate extending toward the target component from the second end of the via.

14. The IC of claim 13, wherein:
the plate is longer than the via in a longitudinal direction perpendicular to the lamination direction and the lateral direction.

15. The IC of claim 12, wherein the plurality of thermally conductive structures is arranged along a longitudinal direction perpendicular to the lamination direction and the lateral direction.

16. The IC of claim 15, further comprising:
a first end electrical connection in contact with a first region of the heating element; and
a second end electrical connection in contact with a second region of the heating element,
wherein:
the plurality of thermally conductive structures is located between the first region and the second region along the longitudinal direction; and
the first end electrical connection and second end electrical connection are configured to pass an electrical current between the first region and the second region through the heating element.

17. The IC of claim 16, wherein:
the target component has a first portion and a second portion;
the first portion is in the longitudinal direction from the second portion;
in operation, the second portion self-heats to a greater degree than the first portion; and
the plurality of thermally conductive structures is arranged non-uniformly along the longitudinal direction such that, when the electrical current is passed through the heating element, the plurality of thermally conductive structures radiates a greater amount of heat toward the first portion of the target component than toward the second portion of the target component.

18. The IC of claim 16, wherein:
the heating element comprises a plurality of heating element segments spaced apart from each other along the longitudinal direction; and
each thermally conductive structure comprises:
a first electrically conductive via having:
a first end in contact with a respective first one of the plurality of heating element segments; and
a second end;
a second electrically conductive via having:
a first end in contact with a respective second one of the plurality of heating element segments; and
a second end; and
an electrically conductive plate joining the second end of the first via to the second end of the second via,
such that the current passes between the first region and the second region through each heating element segment and each thermally conductive structure.

19. The IC of claim 12, wherein:
the heating element is spaced apart from, and at least partially overlapping, the target component in the lamination direction; and
the IC further comprises:
a further plurality of thermally conductive structures extending from the heating element through one or more of the plurality of layers of the IC, the further plurality of thermally conductive structures overlapping at least a portion of the target component in a direction opposite the lateral direction.

20. A method of manufacturing an integrated circuit (IC), comprising:
forming a plurality of layers of the IC stacked in a lamination direction;
forming a target component within a first one or more of the layers of the IC;
forming a heating element within a layer of the IC;
forming a plurality of thermally conductive vias through at least one of the first one or more layers, such that a first end of each via contacts the heating element, and such that at least one of the thermally conductive vias is in a lateral direction, perpendicular to the lamination direction, from the target component; and
forming, in contact with a second end of each via, a thermally conductive plate.
